(19) United States
(12) Patent Application Publication
(10) Pub. No.: US 2024/0291189 A1
(43) Pub. Date: Aug. 29, 2024

(54) CONNECTION DEVICE

(71) Applicant: Erbe Elektromedizin GmbH, Tuebingen (DE)

(72) Inventor: Falk HATZFELD, Tuebingen (DE)

(21) Appl. No.: 18/440,693

(22) Filed: Feb. 13, 2024

(30) Foreign Application Priority Data
Feb. 24, 2023 (EP) 23158562.1

(51) Int. Cl. H01R 13/40; H01R 13/502

(52) U.S. Cl. CPC H01R 13/40; H01R 13/502; H01R 2201/12

(57) ABSTRACT

Connector arrangements having a connector housing and a connector insert arranged therein, which is preferably produced from a multilayer circuit board. The connector insert includes contact elements arranged opposite one another, which are supported by the circuit board material respectively. Mechanical forces acting on the contact elements during insertion of a plug contact are transmitted onto the housing parts and supported by them. The connector arrangements can be provided in a very simple manner and provide additional functions apart from their original function of the electrical connection of a medical instrument with a supplying apparatus, such as protective functions or control functions, for example for correct insertion of plugs or an information technology communication with the latter via contacts or NFC chips or the like.

This application claims priority to European Patent Application No. 23158562.1, filed Feb. 24, 2023, the entirety of which is incorporated by reference herein.

The invention refers to a connection device, particularly for electrical connections on apparatuses for connection and supply of medical instruments, for connection of apparatuses among each other or also for connection of apparatuses with other components.

For electrical connection of apparatuses, for example laptops, with other electrical devices, connectors are known that consist of components, which are movable relative to one another. For example, US 2007/0190862 A1 discloses a connector having a movable wall so that the connector is transferred into a flattened form when closing the laptop.

From CN 104064900 A and CN 202423682 U foldable socket strips are known.

DE 10 2014 105 224 A1 discloses an apparatus having a housing and a circuit board arranged therein, which is provided with electrical components. The circuit board comprises multiple sections that can be bent relative to one another.

In the supply of medical instruments, a reliable transmission of electrical power to the instrument and, if applicable, also a reliable transmission of signals coming from the instrument is important. It is the object of the invention to achieve this with modern production methods and little effort.

This object is solved by a connector arrangement according to claim 1:

The connector arrangement according to the invention comprises a connector housing in which a connector insert is arranged. The connector insert consists of a two-dimensional insulating material folded at bending locations provided for this purpose and electrical conductors arranged thereon and/or therein.

The insulating material can be a planar plate-like body, such as circuit board material, as it is otherwise used for production of electrical and electronic circuits. For example, it can be a plastic material, a fiber-reinforced plastic material or other electrically insulating materials. The conductors can be arranged at least on one side of the plate-like insulating material and/or in the body thereof, that is in an intermediate plane. The insulating material can comprise one or more conducting planes. Thereby different electrical functions can be provided and combined with one another. For example, one conducting plane can serve as shielding while other conducting planes can serve for electrical connection of contacts and/or electrical or electronic components, which can be attached in or on the insulating material.

The insulating material can support one or more contact elements, for example contact springs, contact lamellae, contact terminals or the like, which are connected with one or more conductors of the connector insert. The conductors of the connector insert are preferably configured to directly connect the contact elements with connector ports. The connector ports can be configured as plug contacts, for example as plug contact areas supported by the insulating material. As necessary electrical components can be arranged and can be effective between the contact elements and/or the connector ports, such as resistors, diodes, capacitors or active components, such as electronic switches or electronic circuits. The connector insert can support electrical or electronic circuits, which are connected with the contact elements as well as with the connector ports. The connector insert can also support electrical or electronic circuits, which are only connected with the contact elements or with the connector ports.

The bending locations provided on the connector insert are preferably line-shaped areas, which in turn are configured in a manner extending along straight lines. Thereby a bending of different sections of the otherwise rigid plate-shaped insulating material is possible without warping thereof. For this purpose, the insulating material comprises at least two parallel bending locations at which the insulating material is preferably bent in a right angle. In this manner it can be guaranteed that the connector insert in the connector housing comprises two areas, which are held in parallel manner relative to one another and thus arranged opposite with distance. The interstice formed in this manner can serve for locating of plug contacts of a plug therein, for example of a medical instrument. Contact elements, such as contact springs or the like, can be arranged on the areas of the insulating material that are located with distance opposite one another.

If the insulating material is configured as circuit board a plug recognition can be provided. For example, the latter can be realized in that an electronic circuit arranged on the circuit board applies a test voltage or a test current to the concerned contact elements, so that it can be determined whether the contact elements are connected with one another by a plug element. In addition, it is possible to arrange one or more contacts on the circuit board material, particularly on the two areas thereof located opposite one another, whereby the one or more contacts are in contact with one another in a rest condition and are separated from one another by an insulating body during insertion of a plug. Also, light barriers or similar plug recognition mechanisms, NFC chips for plug identification or the like can be arranged on or in the insulating material or integrated therein in a simple and comfortable manner. Thereby, the concept according to the invention provides a wide area of development possibilities of electrically and mechanically robust connector arrangements, which fulfill numerous safety-relevant additional functions.

The insulating material can also comprise bending locations, which are not orientated parallel to one another and in this manner enclose an interior not only on three or four sides, but also on five sides. This can be used for enlarging the scope of functions.

The bending locations can be formed by grooves formed in the insulating material, that is weakened zones in which the stiffness of the insulating material is reduced locally resulting from the local reduction of thickness thereof. The remaining weakened zone of the insulating material can be elastically or also plastically deformable. It can form a kind of film hinge. Preferably one, multiple or all bending locations in the insulating material are only unilaterally formed, so that conductors arranged on the non-grooved side of the insulating material are not interrupted at the bending location. Thereby an electrical connection between different areas of the plate-shaped insulating material is possible so that the connector insert can be used as spatial circuit board for contacting of all provided contacts and as necessary, also for operation of electrical components and parts.

It is possible to configure the insulating material as seamless monolithic planar plate having weakened zones that define the desired bending locations. Alternatively, it is possible to form one, multiple or all bending locations by a flexible conductor support, which mechanically and/or electrically connects sections of the insulating material, which are separated from one another at the bending locations. Such flexible conductor supports can also be used to releasably or non-releasably electrically connect the connector insert with other components of an electrical apparatus.

The connector insert can have one or more cavities or other openings through which one or more projections of the connector insert or other guide bodies pass. For example, such a guide body can be configured as plug guide, pin guide or the like in order to provide a function of plug guidance or the like.

Additional details of advantageous embodiments of the invention are subject matter of the drawing as well as the associated description or of dependent claims. The drawing shows:

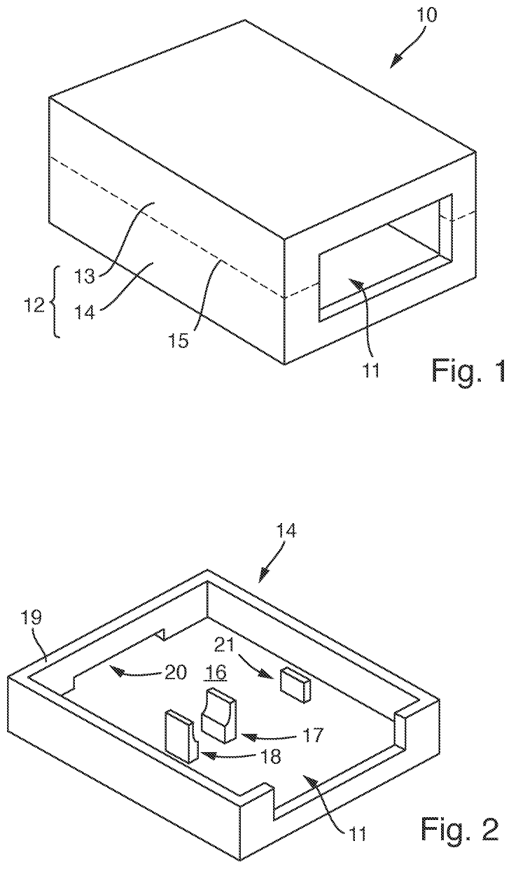

FIG. 1 illustrates a schematic perspective of an embodiment of a connector arrangement having a connector housing;

FIG. 2 illustrates a schematic perspective of an embodiment of a part of the connector housing according to FIG. 1;

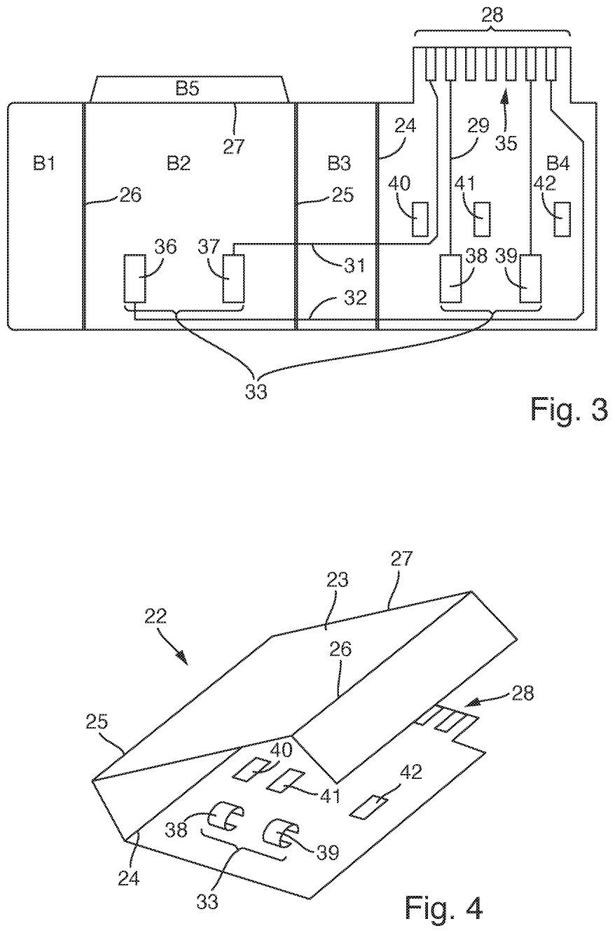

FIG. 3 illustrates a top view of an open perspective of an embodiment of a connector insert having a plate-shaped insulating material;

FIG. 4 illustrates a partially constructed, angled perspective of the connector insert of FIG. 3 formed of an insulating material;

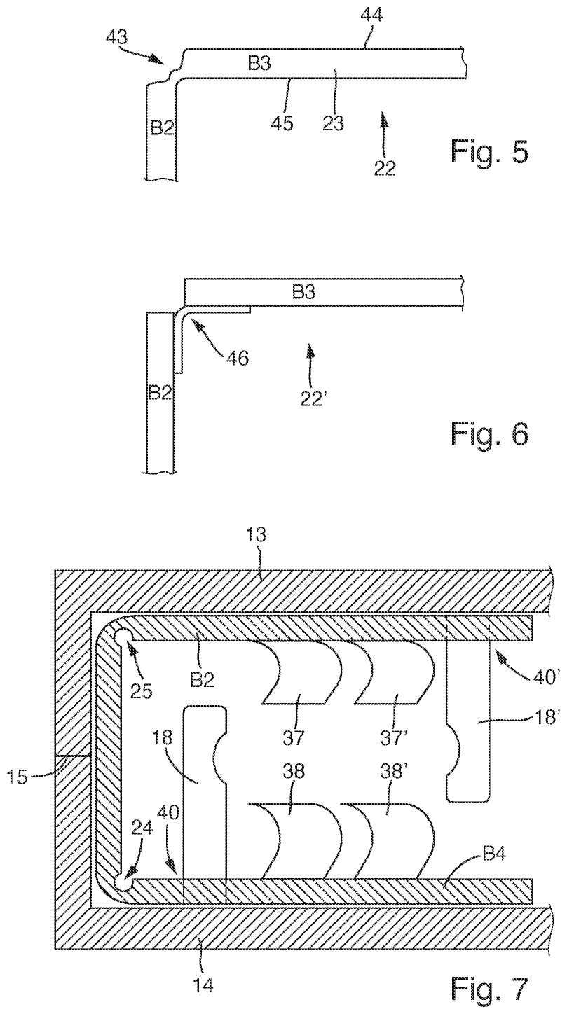

FIG. 5 illustrates a corner section of the connector insert according to FIG. 4 in an enlarged front view;

FIG. 6 illustrates a second embodiment of a connector insert;

FIG. 7 illustrates the connector arrangement according to FIG. 1 in partly vertical sectional illustration;

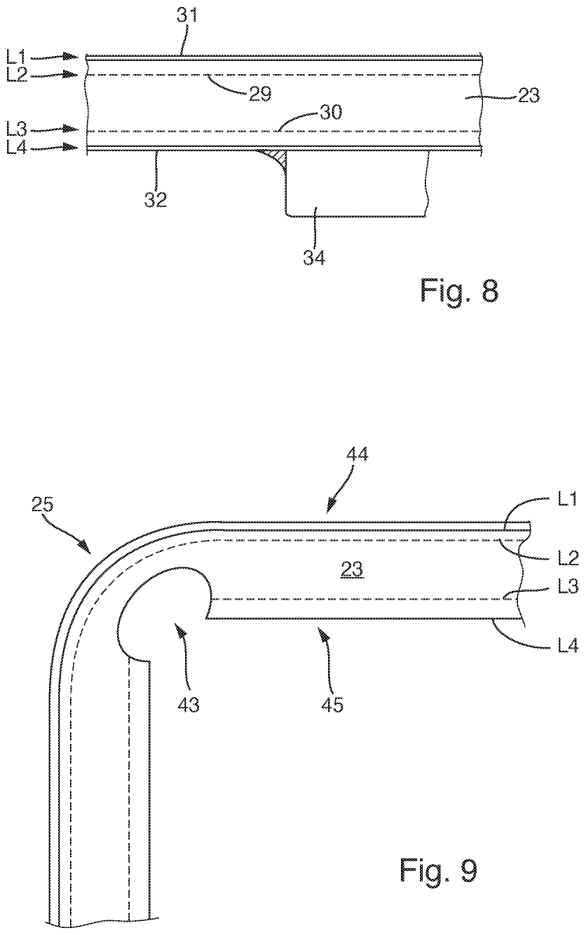

FIG. 8 illustrates the insulating material having multiple conducting planes and an electronic component arranged thereon; and

FIG. 9 illustrates the connector arrangement of FIG. 5 in enlarged illustration.

In FIG. 1 the connector arrangement 10 according to the invention is illustrated, which can be part of an electrical apparatus. The apparatus can be particularly an apparatus for supply of medical instruments, which comprise a not further illustrated plug serving for contacting the instrument. Such a plug is to be inserted into the connector arrangement 10 at an opening 11.

The connector arrangement can be configured as part of an apparatus housing or as separate component. It comprises a connector housing 12, which comprises an upper housing part 13 and a lower housing part 14. In the connector housing illustrated in FIG. 1, the housing parts 13, 14 abut against one another at a center plane or separation line 15. The separation into the upper and lower housing part 13 and 14 can be realized, however, also at another location or with another orientation, so that the connector housing is separated vertically into a right and a left housing part or into a front or a back housing part. Similarly, connector housing 12 can consist of multiple housing parts or can also be configured monolithically. In the latter case it can be open on its back side opposite its opening 11, for example.

FIG. 2 illustrates the lower housing part 14 individually with removed upper housing part. As apparent, the interior enclosed by housing parts 13, 14 can be provided with guide bodies 17, 18 or other parts projecting from the inner side of housing part 14 into the interior 16. For example, guide bodies 17, 18 can serve for guiding of contact pins of the not further illustrated plug or for other purposes. They can be configured monolithically with housing parts 13, 14 or can be attached on the housing parts 13, 14 in another manner.

The housing part 14 (and/or the housing part 13) can be provided with a connection opening 20 at a suitable position, for example on the back side 19, wherein the connection opening 20 can be configured as flat slot, for example. Apart from the guide bodies 17, 18, also other function elements 21 can be provided on housing part 14, for example in form of inwards extending projections.

A connector insert 22 located in connector housing 12 is part of the connector arrangement 10 according to the invention. The connector insert 22 is individually illustrated in FIG. 4. As apparent, connector insert 22 is made from a rigid plate-shaped insulating material 23 that can be bent along multiple, preferably straight, line-shaped bending locations 24 to 27. It can be circuit board material.

FIG. 3 illustrates the production of connector insert 22 starting from an initially preferably planar, flat insulating material, such as circuit board material. This insulating material consists preferably of plastic, for example fiber-reinforced plastic, and comprises conducting paths 29, 30, 31, 32 in at least one plane L1, L2, L3, L4. The conducting paths 29 to 32 can serve to connect the connector ports 28 with socket contacts 33 serving for contacting a plug to be inserted into the connector arrangement 10. The conducting paths 29 to 32 are illustrated in FIG. 3 in one single plane. As indicated in FIG. 8, the conducting paths 29 to 32 as well as additional other conducting paths can also be arranged in different conducting planes L1, L2, L3, L4, which are arranged on the flat sides of the insulating material 23 or also inside the body thereof. The conducting paths are preferably conducting paths made of copper or another metal. The conductor pattern formed by the conducting paths can also serve for contacting electronic circuits, for example comprising electrical or electronic components 34, which can be placed on the insulating material 23.

As illustrated in FIG. 3, the connector ports 28 can be formed by plug contact areas 35, which are formed on a circuit board projection, which can pass through the connection opening 20 of housing part 14, for example. The socket contacts 33 can comprise multiple contact elements 36 to 39, which are formed by contact springs, for example, as indicated in FIG. 4.

In addition, the insulating material 23 can have one or more through-holes 40, 41, 42 through which the guide bodies 17, 18 or the other function element 21 may extend.

The bending location 25 of insulating material 23 is particularly apparent from FIG. 9. The other bending locations 24, 26, 27 can be configured similarly or identically. The insulating material 23 is provided with a groove 43 for forming the bending location 25 at which the insulating material 23 is remarkably weakened. Preferably the thickness to be measured between the two flat sides 44, 45 is reduced by more than half, so that the bending location 25 is flexible compared to the insulating material 23 that has to be considered as being rather rigid apart from the bending location. At the bending location the insulating material can be deformable plastically or elastically.

Preferably, groove 43 faces the interior 16. Further preferably groove 43 does not interrupt all of the conducting planes L1 to L4. Particularly, the conducting planes L1, L2 can be maintained so that an electrical connection between different areas B4 to B5 of the connector insert separated by bending locations 24 to 27 is possible, wherein the connector insert is made from multi-layer circuit boards, for example (FIG. 3).

In principle, it is also possible to provide groove 43 on the outer side of connector insert 22, as illustrated in FIG. 5. In this case, at least conducting plane L4—however, preferably conducting plane L3—is maintained in order to in turn allow an electrical connection between the different areas B1 to B5 of connector insert 22.

As FIG. 6 depicts, such a corner connection can also be provided by individual corner connectors 46. While the connector inserts 22 in which the bending locations 24 to 27 are formed by a groove are seamlessly monolithic, the connector inserts 22′ according to FIG. 6 can consist of different parts. For example, the areas B2, B3, etc. can be first provided separately from one another and in the following connected by corner connectors 46. For example, corner connectors 46 can consist of flexible material, as it is known as flexible circuit board, or similar material. In addition, it is possible to provide a connector insert 22 in which the bending locations 24 to 27 are created by different of the here disclosed types.

FIG. 7 illustrates a slightly modified embodiment of the connector arrangement 10. The contact elements 37, 38 provided in the areas B4, B2 of the circuit board are arranged opposite one another, so that contact pins can be located therebetween. In addition, guide body 18 extends through through-hole 40. Similarly, a guide body 18′ of upper housing part 13 can pass through a respective through-hole 40′ of area B2. In addition, additional contact elements 37′, 38′ can be provided between the two guide bodies 18, 18′. An electrical connection is provided by appropriately arranged conducting paths extending over bending locations 24, 25. In addition, insulating material 23 serving as circuit board can comprise additional elements such as electronic or electrical components. For example, the latter can serve to detect a current flow between opposite contact elements 37, 38 in order to extrapolate the presence or non-presence of contact pins. Additional electrical functions or safety functions can be realized, for example by conducting paths serving as a fuse or components for electrical protection, for example overvoltage protection, or conductor sections for electrical shielding and the like functions.

The connector arrangement 10 described so far can be produced in simple manner from premanufactured housing parts 13, 14 and a respectively formed single-layer or multiple-layer circuit board of insulating material 23 and conducting paths. The circuit board provided with the desired conductor pattern is equipped with the required contact elements 36 to 39, for example contact springs, for this purpose. Prior to this or subsequently, bending locations 24 to 27 can be created in that respective weakened zones are provided, for example in the form of grooves. Alternatively, the areas B1 to B5 can be provided individually and can be mechanically and electrically connected with one another by flexible connection elements according to the example of FIG. 6. The circuit board according to FIG. 3, provided and equipped in this manner is then folded at the bending locations 24 to 27, as indicated in FIG. 4 and inserted into the lower housing part 14, wherein the guide bodies 17, 18 or other function elements 21 extend through the through-holes or openings 40 to 42 provided in the circuit board. For closing the housing arrangement 10 the upper housing part 13 is placed onto the lower housing part 14 and is connected with the latter by a suitable method, for example gluing, ultrasonic welding or by screw or latch or other connectors, whereby the connector arrangement 10 is functional.

The connector arrangement according to the invention comprises a connector housing 12 and a connector insert 22 arranged therein, which is preferably produced from a multilayer circuit board. The connector insert 22 comprises contact elements 37, 38 arranged opposite one another, which are supported by the circuit board material respectively. Mechanical forces acting on the contact elements 37, 38 during insertion of a plug contact are transmitted onto the housing parts 13, 14 and supported by them.

With the concept according to the invention very reliably operating connector arrangements can be provided in very simple manner, which can provide additional functions apart from their original function of the electrical connection of a medical instrument with a supplying apparatus, such as protective functions or control functions, for example for correct insertion of plugs or an information technology communication with the latter via contacts or NFC chips or the like.

1. A connector arrangement for a medical apparatus, comprising:
a connector housing and a connector insert held by the connector housing, the insert having
a two-dimensional insulating material folded at bending locations and electrical conductors arranged on or in the insulating material.

2. A connector arrangement in accordance with claim 1, wherein the bending locations are line-shaped areas.

3. A connector arrangement in accordance with claim 1, wherein the bending locations are configured extending along straight lines.

4. A connector arrangement in accordance with claim 1, wherein the insulating material has at least two line-shaped bending locations a parallel to one another.

5. A connector arrangement in accordance with claim 1, wherein the connector insert is immovably held in the connector housing.

6. A connector arrangement in accordance with claim 1, wherein the insulating material is configured as a rigid plate having multiple areas (B1 to B5) connected to one another via the bending locations.

7. A connector arrangement in accordance with claim 1, wherein the insulating material is a plastic material, preferably a plastic composite material.

8. A connector arrangement in accordance with claim 1, wherein the bending locations are formed by grooves formed in the insulating material.

9. A connector arrangement in accordance with claim 8, wherein the grooves are open toward an interior enclosed by the insulating material.

10. A connector arrangement in accordance with claim 1, wherein the connector insert encloses an interior at least at three sides.

11. A connector arrangement in accordance with claim 1, wherein the connector insert is elastically deformable at the bending locations.

12. A connector arrangement in accordance with claim 1, wherein the insulating material of the connector insert is seamlessly monolithically configured.

13. A connector arrangement in accordance with claim 1, wherein the bending locations are formed by a flexible conductor support, which mechanically or electrically connects areas (B1 to B5) of the insulating material with one another, which are separated from one another at the bending location.

14. A connector arrangement in accordance with claim 1, wherein the at least one contact body is held on the insulating material.

15. A connector arrangement in accordance with claim 1, wherein the insulating material comprises at least one through-hole and that at least one guide body is arranged on the connector housing, which is arranged in a manner passing through the through-hole.
